(19) United States
(12) Patent Application Publication
(10) Pub. No.: US 2013/0063141 A1
(43) Pub. Date: Mar. 14, 2013

(54) APPARATUS AND METHOD FOR IDENTIFYING MAGNETICALLY MARKED MICRO OBJECTS

(71) Applicants: Karsten Hiltawsky, Schwerte (DE); Roland Weiss, Erlangen (DE)

(72) Inventors: Karsten Hiltawsky, Schwerte (DE); Roland Weiss, Erlangen (DE)

(73) Assignee: SIEMENS AKTIENGESELLSCHAFT, Munich (DE)

(21) Appl. No.: 13/698,526

(22) PCT Filed: May 13, 2011
(86) PCT No.: PCT/EP2011/057789

§ 371 Date: Nov. 16, 2012

(30) Foreign Application Priority Data
May 18, 2010 (DE) 10 2010 020 785.3

(51) Int. Cl. G01R 33/02

(52) U.S. Cl. 324/244

(57) ABSTRACT

An apparatus is disclosed for identifying magnetically marked micro objects, in particular biological micro objects, preferably tumor cells. In at least one embodiment, the apparatus includes a carrier for at least one micro object; a device for applying a region with a magnetic gradient field, wherein the gradient field comprises at least one zero point; a device for applying the micro object with a high frequency magnetic field, in particular at the site of the zero point; a device for relative movement of the carrier and region to one another; a device for receiving a change in a magnetic flux through the micro object; a device for evaluating the received change in the magnetic flux and for identifying the position of the micro object; and a device for in particular automatically analyzing the micro object.

### PRIORITY STATEMENT

This application is the national phase under 35 U.S.C. §371 of PCT International Application No. PCT/EP2011/057789 which has an International filing date of May 13, 2011, which designated the United States of America, and which claims priority to German patent application number DE 10 2010 020 785.3 filed May 18, 2010, the entire contents of each of which are hereby incorporated herein by reference.

### FIELD

At least one embodiment of the invention generally relates to an apparatus for identifying magnetically marked micro objects, in particular tumor cells and/or to a corresponding method.

### BACKGROUND

Micro objects, such as for instance tumor cells, are provided with magnetic micro or nano particles for their identification or localization. In order now to be able to differentiate these from healthy cells, on account of the low concentration of marked cells to be expected, these have to be identified in a medium, for instance blood, using a high resolution method.

Enabling a detection of tumor cells by way of a multi-stage method is herewith known from a reference. For this purpose, a blood sample of a patient is initially freed of red blood cells, i.e. hemolyzed. Possible tumor cells are then magnetically marked and enriched. The cells are then fluorescently colored against specific antigens or cell nucleus components, so that tumor cells of leukocytes can be differentiated by means of a fluorescence analysis. The afore-cited processing steps frequently however result in the explosion of cells, so that the cell components of the exploded cells are smeared and can no longer be identified.

This method requires a complicated and cost-intensive preparation for the analysis of tumor cells. On account of the low concentration in the blood, these have to be enriched in a complex manner in order to enable a detection. Cells are simultaneously frequently destroyed by these processing steps, which hampers the identification of tumor cells.

### SUMMARY

An apparatus and method are disclosed wherein, in at least one embodiment, no complex preparation or processing is required to identify the micro objects. At least one embodiment of the method or the apparatus enables a high number of micro objects to be examined and detected at a simultaneously high resolution and data speed, which overall enables a simpler, quicker and more cost-effective method and/or apparatus.

According to an advantageous development of at least one embodiment of the invention, the carrier includes a coating to increase the frictional value, in particular polylysine. The advantage here is that micro objects which are to be identified remain on the coated carrier when accelerating the carrier in its position. The carrier can therefore be moved more quickly, in particular directional changes can be implemented more quickly without significantly changing the position of the micro objects. This enables quicker identification of the magnetically marked micro objects.

### BRIEF DESCRIPTION OF THE DRAWINGS

Example embodiments of the invention are displayed in the drawings and explained in further detail in the subsequent description, in which:

FIG. 1 shows a schematic diagram of an apparatus according to a first embodiment of the present invention;

FIG. 2 shows a schematic diagram of an apparatus according to a second embodiment of the present invention;

FIG. 3 shows a schematic diagram of an apparatus according to a third embodiment of the present invention;

FIG. 4 shows a transmit and receive coil of an apparatus according to a fourth embodiment of the present invention;

FIG. 5 shows method steps of a method according to a first embodiment of the present invention

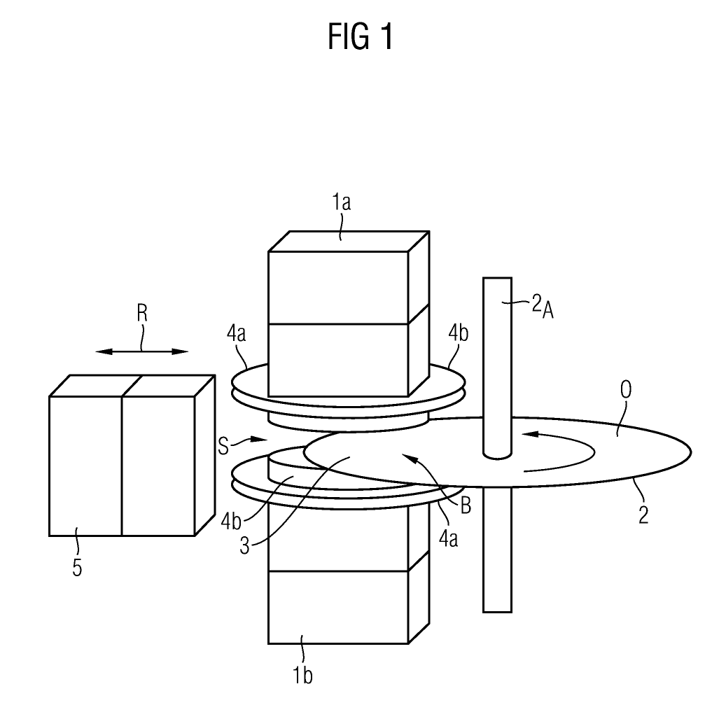

FIG. 1 shows a schematic diagram of an apparatus according to a first embodiment of the present invention.

### DETAILED DESCRIPTION OF THE EXAMPLE EMBODIMENTS

According to an advantageous development of at least one embodiment of the invention, the carrier includes a coating to increase the frictional value, in particular polylysine. The advantage here is that micro objects which are to be identified remain on the coated carrier when accelerating the carrier in its position. The carrier can therefore be moved more quickly, in particular directional changes can be implemented more quickly without significantly changing the position of the micro objects. This enables quicker identification of the magnetically marked micro objects.

According to a further advantageous development of at least one embodiment, the device for analysis includes a micro manipulator for receiving the micro object. The advantage here is that after identifying the position of the micro object, this can therefore be easily and quickly received without damage and transported to an analysis apparatus for analysis.

According to a further advantageous development of at least one embodiment of the invention, the device for analysis include an optical device, in particular a microscope. The advantage here is that the reliability of the analysis of the micro object is thus increased, since the identified magnetically marked micro objects are controlled using optical means. Furthermore, if the optical device includes a microscope, a lab technician can additionally optically examine the magnetically marked and identified micro object him/herself so that the reliability and the accuracy of the analysis of the micro object is further increased.

According to a further advantageous development of at least one embodiment of the invention, the device for relative movement includes at least one device for generating a magnetic field for displacing the magnetic gradient field. The advantage here is that provision does not have to be made for additional mechanical components for the relative movement of the device in order to apply the micro object with a magnetic gradient field and the carrier and also the means for receiving a change in a magnetic flux, which on the one hand further increases the reliability of the apparatus, while on the other hand reducing the costs for the apparatus.

According to a further advantageous development of at least one embodiment of the invention, the carrier is embodied as a rotatable disk or rectangular plate, in particular made of glass. The advantage here is that simple and cost-effective carriers are therefore available.

According to a further preferred development of at least one embodiment of the invention, the device for applying the object with a high frequency magnetic field and the device for receiving a change in a magnetic flux are mutually arranged on one side of the carrier. The advantage here is that the space required for the apparatus reduces significantly and this can be embodied in a more compact manner. The flexibility of the apparatus increases at the same time, since additional components in the region of the carrier can be arranged on the side facing away from the device for applying and the device for receiving.

According to a further preferred development of at least one embodiment of the invention, the device for applying the object with a high frequency magnetic field and the device for receiving a change in a magnetic flux are arranged coaxially around a shared axis. The advantage here is that the space required for the apparatus to identify magnetic marked micro object is reduced still further and the flexibility of the apparatus is simultaneously increased still further.

In FIG. 1, reference characters 1a, 1b denote a device for generating a magnetic gradient field. Here the device 1a, 1b according to FIG. 1 are arranged one above the other in the form of magnets and are distanced from one another by way of a gap S. Transmit coils 4a and receive coils 4b directly adjacent to the gap S are arranged on the sides of the magnets 1a, 1b facing the gap S. The transmit coils 4a are used for this purpose to emit a high frequency signal in order to apply a micro object O on the carrier 2 arranged in the form of a rotatable disk. The disk 2 can be rotated about an axis 2A and protrudes with its sub region B of its surface into the gap S between the magnets 1a, 1b and the transmit coils 4a and the receive coils 4b.

The magnetic gradient field in this way includes a magnetic field-free point 3, which is arranged in the plane of the rotatable disk 2 or the micro objects O on the rotatable disk 2. In the magnetic field-free point 3, which actually corresponds essentially to a very small elliptically formed field-free region, the micro object O experiences a reversal of magnetism due to high frequency signals of the transmit coils 4a, which can be measured by the receive coils 4b. This enables a tumor cell to be sufficiently accurately determined for instance in respect of its position on the carrier 2.

In order to enable all micro objects O on the rotatable disk 2 to be examined, the disk is embodied to be rotatable about an axis 2A, which, as already described above, protrudes with a sub region B into the gap S between the magnets 1a, 1b and the transmit and receive coils 4a, 4b. In order now to be able to detect all micro objects O on the surface of the rotating disk 2, the magnetic field-free point 3 is displaced by means of a magnet 5, the magnetic field strength and/or position relative to the magnetic 1a, 1b or axis 2A of which can be varied, at right angles to axis 2A of the rotating disk 2 according to its magnetic field strength. By rotating the disk 2 and displacing the magnetic field-free point 3 by way of the magnetic field of the magnet 5, all regions of the surface of the disk 2 with the magnetic field-free point 3 can be applied one after the other with the high frequency field which is generated by the transmit coil 4a.

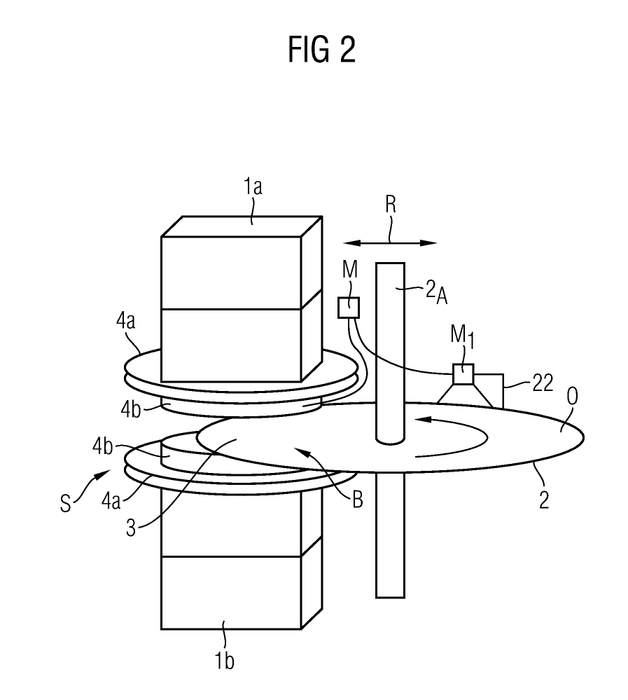

FIG. 2 shows a schematic diagram of an apparatus according to a second embodiment of the present invention.

FIG. 2 essentially shows a similar structure of the apparatus according to FIG. 1. Contrary to FIG. 1, the axis 2A of the rotating disk 2 is now arranged so as to be displaceable in direction R instead of the magnet 5 with corresponding magnetic field for displacing the magnetic field-free point 3. The magnetic field-free point 3 is now stationary. Displacement of the axis 2A in the horizontal direction R enables the sub region B of the rotating disk 2, which protrudes into the gap S, to be displaced. It is likewise possible in this way to apply all regions of the surface of the rotating disk 2, on which micro objects O are disposed, with the magnetic field-free point 3 and naturally with the high frequency field of the transmit coils 4a.

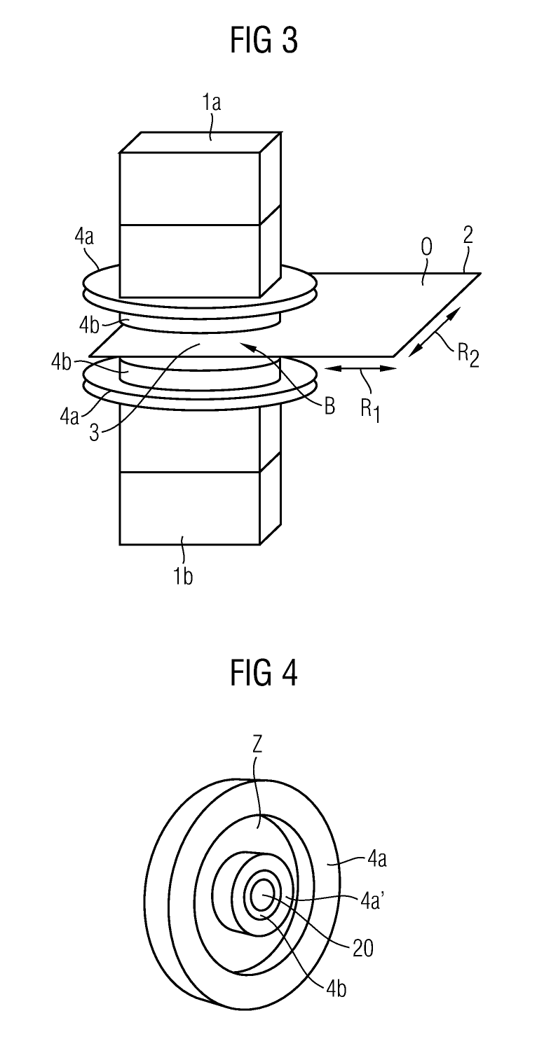

Furthermore in FIG. 2 and also in FIGS. 1 and 3, the receive coils 4b are connected to evaluation facilities M. The evaluation facility M evaluates the received change in the magnetic flux of the micro object O and therefrom determines its respective position. This evaluation facility M can be embodied such that this can record and evaluate an optical image of the surroundings of the field-free point 3. Furthermore, the evaluation facility M is connected to an analysis facility M1. The analysis facility M1 in this process includes a micro manipulator 22, in order to be able to record the identified micro object O and to be able to supply the analysis facility M1 for further analysis.

FIG. 3 shows a schematic diagram of an inventive apparatus according to a third embodiment of the present invention.

In FIG. 3, contrary to FIGS. 1 and 2, a rectangular plate 2 is arranged instead of the rotating disk 2. The rectangular plate protrudes here with a sub region B of its surface, on which the micro objects O are disposed, into the gap S between the magnets 1a, 1b and the transmit and receive coils 4a, 4b. The plate 2 is arranged so as to be displaced along its respective edge in directions R1, R2, so that the magnetic field-free point 3 can apply to each point of the surface of the plate 2 by displacement of the plate 2 along the directions R1 and/or R2 and thereby all micro objects O can be identified on the surface of the plate 2. Conventional means can be used to move the plate 2, for instance linear motors, drives etc.

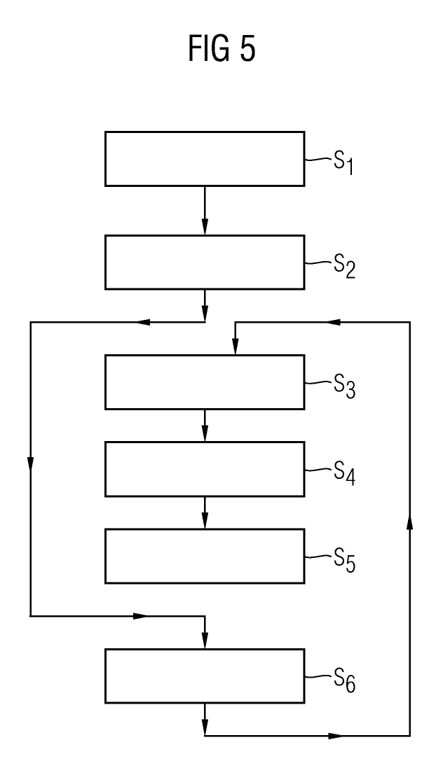

FIG. 4 shows transmit and receive coils of an inventive apparatus according to a fourth embodiment.

The reference characters 4a, 4b, in FIG. 4, and also in FIGS. 1 to 3, denote transmit and/or receive coils. Contrary to FIGS. 1 to 3, the transmit and receive coils 4a, 4b are arranged coaxially around a shared axis 20. The structure from outside inwards is as follows:

A circular transmit coil 4a is arranged on the exterior, said transmit coil 4a being distanced from a further transmit coil 4a′ by means of an intermediate space Z and being arranged coaxially hereto. The gradient field is generated here by way of currents into the coils 4a, 4a′, which flow counter to one another in the respective transmit coil about the axis 20. A receive coil 4b is arranged coaxially on the interior of the coil 4a′. This is used to measure the magnetic field change generated in the micro objects O by a high frequency field.

FIG. 5 shows method steps of a method according to the first embodiment of the present invention for identifying magnetically marked micro objects.

The following steps are implemented here:

Generate S1 a magnetic gradient field, wherein the gradient field includes at least one zero point 3,

Relative movement S2 of a micro object O on a carrier 2 and zero point 3 to one another, wherein the relative movement S2 of the micro object O and the zero point 3 takes place by way of generating S6 a further magnetic field,

Generate S1a a high frequency magnetic field for applying the object O, in particular at the site of the zero point 3,

Receive S3 a change in the magnetic flux through the micro object O,

Evaluate S4 the received change in the magnetic flux and identify the position and/or type of micro object O,

Analyze S5, in particular automatically, the micro object O.

Although the present invention was previously described with the aid of preferred exemplary embodiments, it is not restricted thereto but can be modified in various ways.

1. An apparatus for identifying magnetically marked micro objects, comprising:
a carrier for at least one micro object;
a device, configured to apply a region with a magnetic gradient field, wherein the magnetic gradient field comprises at least one zero point;
a device, configured to apply the micro object with a high frequency magnetic field;
relative movement device, configured to relatively move at least one of the carrier and region to the other of the carrier and region;
a device, configured to receive a change in a magnetic flux through the micro object;
evaluation device, configured to evaluate the received change in the magnetic flux and configured to identify the position of the micro object; and
analysis device, configured to automatically analyze the micro object, wherein the carrier includes a coating to increase the frictional value.

2. (canceled)

3. The apparatus of claim 1, wherein the analysis device includes a micro manipulator for recording the micro object.

4. The apparatus of claim 1, wherein the analysis device includes at least one optical device.

5. The apparatus of claim 1, wherein the relative movement device includes a magnetic field generator configured to generate a magnetic field for displacing the zero point.

6. The apparatus of claim 1, wherein the carrier is embodied as a rotatable disk or rectangular plate.

7. The apparatus of claim 1, wherein at least the device configured to apply the object with a high frequency magnetic field and the device configured to receive a change in a magnetic flux are arranged on a side of the carrier.

8. The apparatus of claim 1, wherein the device configured to apply the object with a high frequency magnetic field and the device configured to receive are arranged coaxially around a shared axis.

9. A method for identifying magnetically marked micro objects, the method comprising:
generating a magnetic gradient field, wherein the magnetic gradient field includes at least one zero point;
relatively moving at least one of a micro object on a carrier and zero point to other one of the micro object on a carrier and zero point;
generating a high frequency magnetic field for applying to the object;
receiving a change in the magnetic flux through the micro object;
evaluating the received change in the magnetic flux and identifying at least one of the position and type of micro object; and
analyzing the micro object, wherein the carrier includes a coating for increasing the frictional value.

10. The method as claimed in claim 9, wherein the analyzing takes place by way of an optical device.

11. The method as claimed in at least claim 9, wherein the relative movement of the micro object and zero point takes place via generation of a further magnetic field.

12. The apparatus of claim 1, wherein the apparatus is for identifying magnetically marked biological micro objects.

13. The apparatus of claim 1, wherein the apparatus is for identifying magnetically marked tumor cells.

14. The apparatus of claim 1, wherein the at least one optical device is a microscope.

15. The apparatus as claimed in claim 6, wherein the carrier is made of glass.

16. The apparatus of claim 1, wherein the carrier includes a coating of polylysine.

17. An apparatus for identifying magnetically marked micro objects, comprising:
a carrier for at least one micro object;
means for applying a region with a magnetic gradient field, wherein the gradient field comprises at least one zero point;
means for applying the micro object with a high frequency magnetic field;
means for relative movement of the carrier and region to one another;
means for receiving a change in a magnetic flux through the micro object;
means for evaluating the received change in the magnetic flux and for identifying the position of the micro object; and
means for automatic analysis of the micro object, wherein the carrier includes a coating to increase the frictional value.

18. The apparatus of claim 16, wherein the means for applying the micro object with a high frequency magnetic field does so at the site of the zero point.

19. The method of claim 9, wherein the generated high frequency magnetic field is applied to the object at the site of the zero point.

20. The method of claim 9, wherein the analyzing is done automatically.

21. The method of claim 9, wherein the carrier includes a coating of polylysine.
